(19) United States
(12) Patent Application Publication
(10) Pub. No.: US 2024/0279838 A1
(43) Pub. Date: Aug. 22, 2024

(54) ELECTROPLATING DEVICE AND ELECTROPLATING METHOD

(71) Applicant: ACM RESEARCH (SHANGHAI), INC., Shanghai (CN)

(72) Inventors: Hui Wang, Shanghai (CN); Hongchao Yang, Shanghai (CN); Jian Wang, Shanghai (CN); Yinuo Jin, Shanghai (CN); Yi Shi, Shanghai (CN); Zheng Zhang, Shanghai (CN)

(73) Assignee: ACM RESEARCH (SHANGHAI), INC., Shanghai (CN)

(21) Appl. No.: 18/568,717

(22) PCT Filed: Apr. 28, 2022
(86) PCT No.: PCT/CN2022/089934

§ 371 Date: Dec. 8, 2023

(30) Foreign Application Priority Data
Jun. 11, 2021 (CN) 202110654975.6

(51) Int. Cl. C25D 17/00; C25D 17/06; C25D 21/12

(52) U.S. Cl. CPC C25D 17/007; C25D 17/06; C25D 21/12

(57) ABSTRACT

Disclosed in an embodiment of the present invention is an electroplating device, comprising an electroplating tank, a clamp, a positioning cylinder and an anode, wherein the positioning cylinder is located in the electroplating tank; the positioning cylinder is open at one end; the anode is located inside the positioning cylinder, and the positioning cylinder comes in contact with the anode in a sealing manner; and in the entire surface region of the anode, only a first surface comes in contact with an electroplating solution, and the first surface is parallel and opposite to a substrate, with the center of the first surface being aligned with the center of the substrate, and the size of the first surface being similar to that of an effective electroplating region of the substrate. By means of the electroplating device, an electric field generated by the anode is uniformly distributed on the surface of the substrate, thereby improving the uniformity of the electroplating height on the surface of the substrate. Further disclosed in an embodiment of the present invention is an electroplating method using the electroplating device.

### BACKGROUND OF THE INVENTION

### 1. Field of the Invention

The present invention generally relates to the field of semiconductor equipment, and more particularly relates to an electroplating device and an electroplating method.

### 2. The Related Art

In an electroplating process, an anode and a substrate are immersed in an electroplating solution, and an electric field is generated on the surface of the anode, under the action of the electric field, metal is gradually deposited on the surface of the substrate. As shown in FIG. 1A, in an existing electroplating equipment, the size of the surface of anode 101 is larger than the size of substrate 102, which will cause the electric field line density at the edge of the substrate 102 to be larger than the electric field line density at the center of the substrate 102, as shown in FIG. 1B, the electroplating height at the edge of the substrate is significantly higher. As shown in FIG. 2, the common solution is to install an edge baffle 204 in the electroplating chamber, and the edge baffle 204 is located between the anode 201 and the substrate 202, covering the outer periphery of the anode 201, so that the size of the uncovered region in the center of the anode 201 is approximately the same as the size of the substrate 202. However, since the outer periphery of the anode 201 also generates an electric field, the electric field can still bypass the edge baffle 204 and reaches the substrate 202, so that the electroplating height at the edge of the substrate 202 is still higher than that of the center of the substrate 202, resulting in uneven electroplating height on the surface of the substrate 202.

In addition, since the electric field is distributed everywhere in the electroplating solution, an electric field is generated on the anode surface that is in contact with the electroplating solution. A surface that generates the electric field is called an effective surface, as shown in FIG. 3A and FIG. 3B, since the side surface of the anode is also an effective surface, it is difficult to control the uniformity of the generated electric field, resulting in uneven electroplating height on the substrate surface.

On the other hand, a metal block acts as an anode, replenishing metal ions consumed in the electroplating solution during the electroplating process. As the process proceeds, the surface of the anode continues to be consumed, the thickness of the anode gradually decreases, and the distance from the surface of the anode to the surface of the substrate (i.e., cathode) gradually increases, and the change in this distance will alter the electroplating deposition rate, increase the difficulty of process control, especially when the electroplated metal layer is very thin, the electroplating process needs to be precisely controlled.

### SUMMARY

One object of the present invention is to provide an electroplating device that uniformly distributes an electric field generated by an anode on the surface of a substrate, thereby improving the uniformity of the electroplating height on the surface of the substrate.

In order to achieve the above object, one embodiment of the present invention provides an electroplating device, comprising:
an electroplating tank, configured to contain electroplating solution;
a clamp, configured to hold the substrate;
a positioning cylinder, located in the electroplating tank, one end of the positioning cylinder is open;
an anode, located inside the positioning cylinder, the positioning cylinder comes in contact with the anode in a sealing manner, in the entire surface region of the anode, only a first surface comes in contact with the electroplating solution, the first surface is parallel and opposite to the substrate, with the center of the first surface being aligned with the center of the substrate, and the size of the first surface being similar to that of an effective electroplating region of the substrate.

Another object of the present invention is to provide an electroplating device that not only uniformly distributes the electric field generated by the anode on the surface of the substrate, thereby improving the uniformity of the electroplating height on the surface of the substrate, but also keeps the distance between the anode and the substrate constant to improve the stability of process results.

In order to achieve the above object, one embodiment of the present invention provides an electroplating device, comprising:
an electroplating tank, configured to contain electroplating solution;
a clamp, configured to hold the substrate;
a positioning cylinder, located in the electroplating tank, and one end of the positioning cylinder is open;
an anode, located inside the positioning cylinder, the positioning cylinder comes in contact with the anode in a sealing manner, in the entire surface region of the anode, only a first surface comes in contact with the electroplating solution, the first surface is parallel and opposite to the substrate, with the center of the first surface being aligned with the center of the substrate, and the size of the first surface being similar to that of an effective electroplating region of the substrate;
a driving device and a controller, the driving device is connected to the anode and the controller respectively, the controller regularly calculates the change in distance between the first surface of the anode and the substrate and controls the driving device, the driving device drives the anode to move toward the substrate to make the distance between the first surface of the anode and the substrate reach a set value.

Another embodiment of the present invention provides an electroplating method, comprising: setting a positioning cylinder in an electroplating tank, and placing an anode inside the positioning cylinder, wherein the inner wall of the positioning cylinder comes in contact with the anode in a sealing manner, so that in the surface region of the anode, only a first surface of the anode is in contact with electroplating solution, the first surface of the anode is parallel and opposite to the substrate, with the center of the first surface of the anode being aligned with the center of the substrate;
setting a driving device in the electroplating tank, wherein the driving device is contacted to the anode, calculating or detecting the change in distance between the first surface of the anode and the substrate, and controlling the driving device moving to make the anode move toward the substrate until the distance between the first surface of the anode and the substrate reaches a set value.

During the electroplating process, the present invention improves the uniformity of the distribution of the electric field by making the size of the cross-section of the electric field generated by the anode similar to that of the effective electroplating region of the substrate, so that the electric field intensity at each place near the effective electroplating region of the substrate can be close to each other, and improves the uniformity of the electroplating height on the surface of the substrate.

### BRIEF DESCRIPTION OF THE DRAWINGS

FIG. 1A illustrates a schematic view of the electric field generated by an anode of an existing electroplating device.

FIG. 1B illustrates the electroplating result curve of the electroplating device in FIG. 1A.

FIG. 2 illustrates a schematic view of the electric field generated by the anode in an electroplating device with an edge baffle.

FIG. 3A illustrates a schematic view of the electric field generated by an anode of an existing electroplating device, wherein the size of the anode is larger than the size of the substrate, and both the side surface and the top surface of the anode generate electric fields.

FIG. 3B illustrates a schematic view of the electric field generated by an anode of an existing electroplating device, wherein the size of the anode is smaller than the size of the substrate, and both the side surface and the top surface of the anode generate electric fields.

FIG. 4 illustrates a schematic view of a cross-sectional structure of an electroplating device in embodiment 1 of the present invention.

FIG. 5 illustrates a schematic view of the electric field generated by the electroplating device in embodiment 1 of the present invention.

FIG. 6 illustrates a schematic view of a cross-sectional structure of the electroplating device in embodiment 1 of the present invention after the electroplating device working for a period of time.

FIG. 7 illustrates a schematic view of a cross-sectional structure of an electroplating device in embodiment 2 of the present invention.

FIG. 8 illustrates a schematic view of a cross-sectional structure of an electroplating device in embodiment 3 of the present invention.

FIG. 9 illustrates a schematic view of a cross-sectional structure of the electroplating device in embodiment 3 of the present invention after the electroplating device working for a period of time.

FIG. 10 illustrates a schematic view of a cross-sectional structure of an electroplating device in embodiment 4 of the present invention.

FIG. 11 illustrates a partially enlarged view of FIG. 10.

FIG. 12 illustrates a schematic view of a cross-sectional structure of an electroplating device in embodiment 5 of the present invention.

FIG. 13 illustrates a schematic view of a cross-sectional structure of an electroplating device in embodiment 6 of the present invention.

### DETAILED DESCRIPTION OF EMBODIMENTS

In order to explain the technical content, structural features, objects and effects of the present invention in detail, the following will be described in detail in combination with the embodiments and drawings.

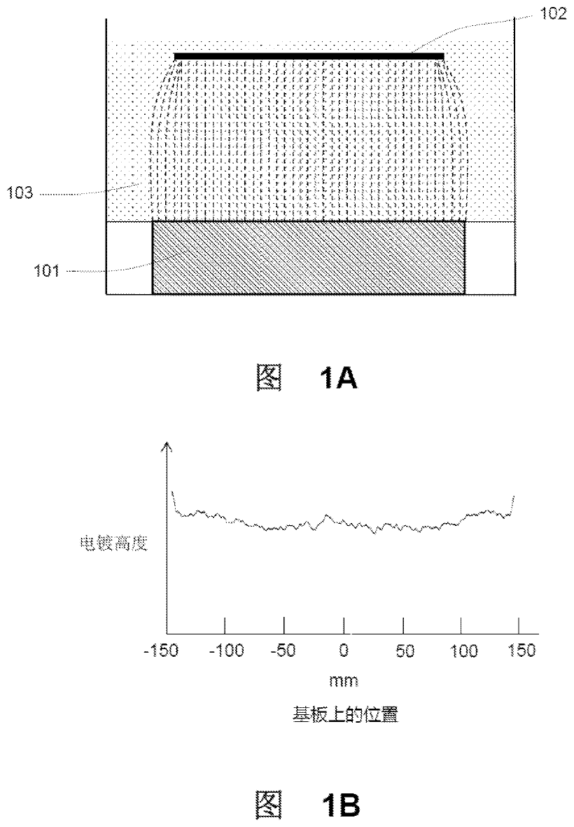

FIG. 1A illustrates an existing electroplating device, in which an anode 101 and a substrate 102 are immersed in an electroplating solution 103, with the substrate 102 acting as a cathode. During electroplating, an electric field is generated on the upper surface of the anode 101, and since the size of the upper surface of the anode 101 is larger than the size of the substrate 102, the electric field lines near the edge of the substrate 102 are denser than those near the center region of the substrate 102, and the intensity of the electric field near the edge of the substrate 102 is greater, and therefore the electroplating height at the edge of the substrate 102 is higher than that of the other regions, and the electroplating result curve is shown in FIG. 1B, the uniformity of the electroplating height on the substrate is poor.

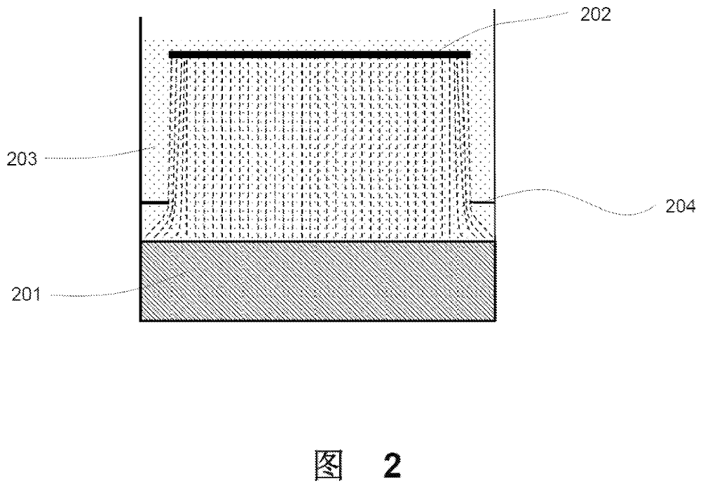

As shown in FIG. 2, in order to attempt to solve this problem, it is common practice to install an edge baffle 204 in the electroplating tank, the edge baffle 204 being annular in shape, disposed between the anode 201 and the substrate 202, shading the outer periphery of the anode 201 in order to block the electric field generated at the outer periphery of the anode 201. However, since the electroplating solution 203 is filled between the surface of the anode 201 and the substrate 202, the electric field generated at the periphery of the anode 201 still bypasses the edge baffle 204 and reaches the substrate 202, so that the electroplating height near the edge of the substrate 202 is still higher than the electroplating height in the rest of the region on the substrate 202.

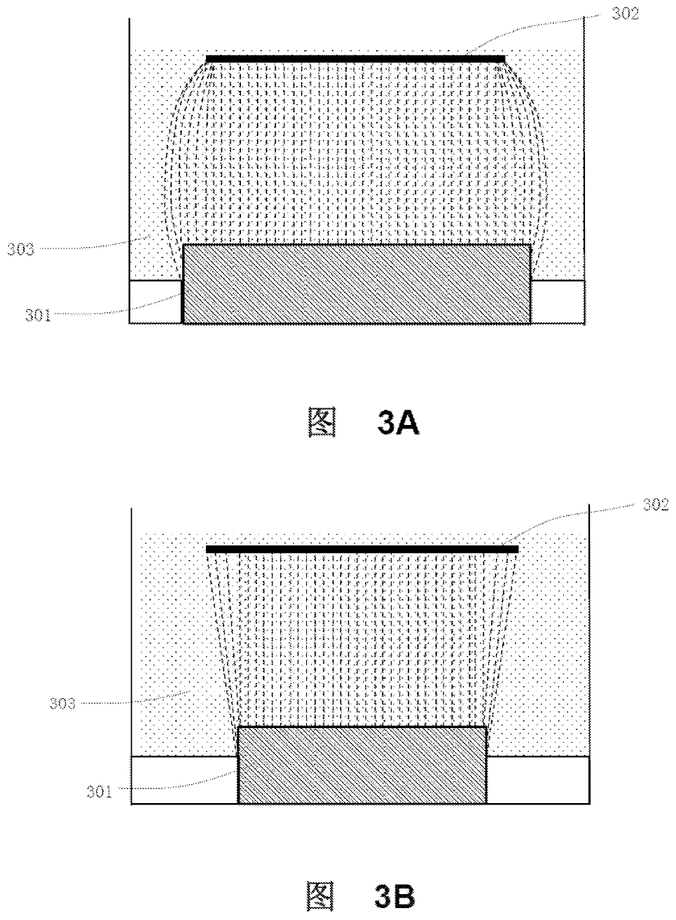

In addition, as shown in FIG. 3A and FIG. 3B, since the side surface of the anode 301 is also immersed in the electroplating solution 303, the side surface of the anode 301 also generates electric field, since it is difficult to control the intensity of the electric field in each place near the substrate, it is difficult to control the electroplating height on the surface of the substrate 302.

In order to uniformly distribute the electric field intensity between the anode and the substrate, the present invention improves the design of the electroplating device and method, as shown in the following embodiments.

### Embodiment 1

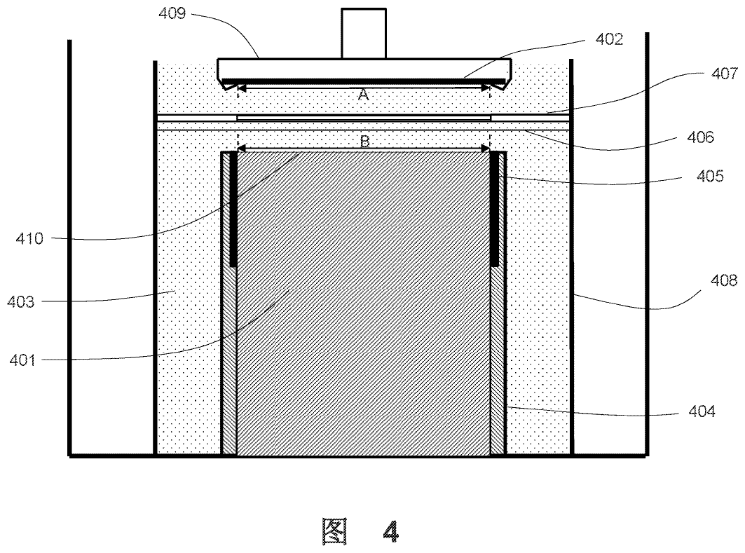

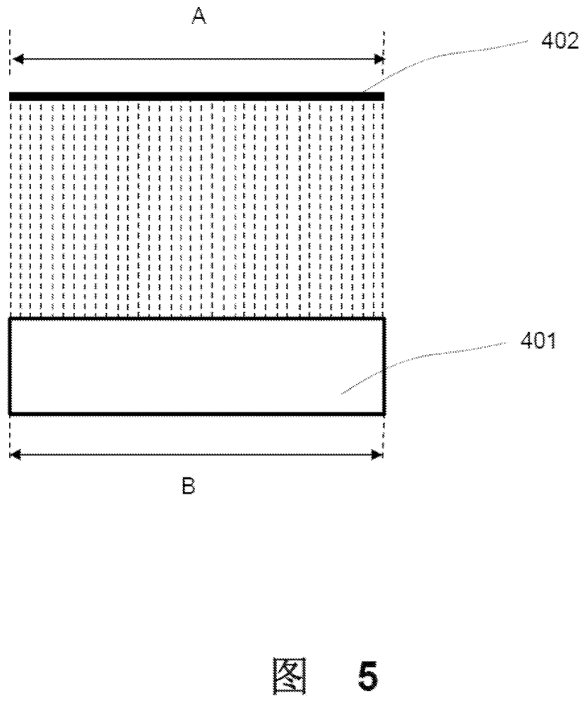

As shown in FIG. 4, this embodiment provides an electroplating device, comprising an anode 401, a positioning cylinder 404, an ion membrane 406, a diffusion plate 407, an electroplating tank 408 and a clamp 409. The electroplating tank 408 is used to contain the electroplating solution 403. The clamp 409 is used to hold the substrate 402. The anode 401 is located below the substrate 402, and an upper surface 410 of the anode 401 is parallel and opposite to the substrate 402. The ion membrane 406 is located above the anode 401, used to separate the anodic electroplating solution and cathode electroplating solution in the electroplating tank 408. The diffusion plate 407 is located between the ion membrane 406 and the substrate 402. The diffusion plate 407 has a plurality of small holes for the electroplating solution 403 to pass through. The positioning cylinder 404 is located in the electroplating tank 408, and the top of the positioning cylinder 404 is open, the bottom of the positioning cylinder 404 is connected to the inner wall of the electroplating tank 408. The anode 401 is located inside the positioning cylinder 404. The shape of the inner wall of the positioning cylinder 404 matches the anode 401, with the center of the upper surface 410 of the anode 401 being aligned with the center of the substrate 402. The positioning cylinder 404 comes in contact with at least the upper portion of the side surface of the anode 401 in a sealing manner, such that in the surface region of the anode 401, only the upper surface 410 of the anode 401 is in contact with the electroplating solution 403, so the electric field generated by anode 401 is emitted entirely from the upper surface 410. The anode 401 may be cylindrical, and the size B of the upper surface 410 of the anode 401 is similar to the size A of the effective electroplating region of the substrate 402, so the size of the cross-section of the electric field generated by the anode 401 is the same (absolutely the same or approximately the same) as the size A of the effective electroplating region of the substrate 402, as shown in FIG. 5, thus, the uniformity of the electric field distribution can be improved, so that the electric field intensity at each place of the effective electroplating region of the substrate 402 can be close to each other, thereby improving the uniformity of the electroplating height on the surface of the substrate 402.

Regarding the effective electroplating region of the substrate 402, this region refers to an region where metal is deposited. For example, when a circular substrate 402 with a diameter of 300 mm is held by the clamp 409, there is an annular region with a width of 1.5 mm on the edge of the substrate 402 that is wrapped by a lip seal of the clamp 409, this annular region will not be deposited with metal, so the diameter of the effective electroplating region of the substrate 402 is 297 mm.

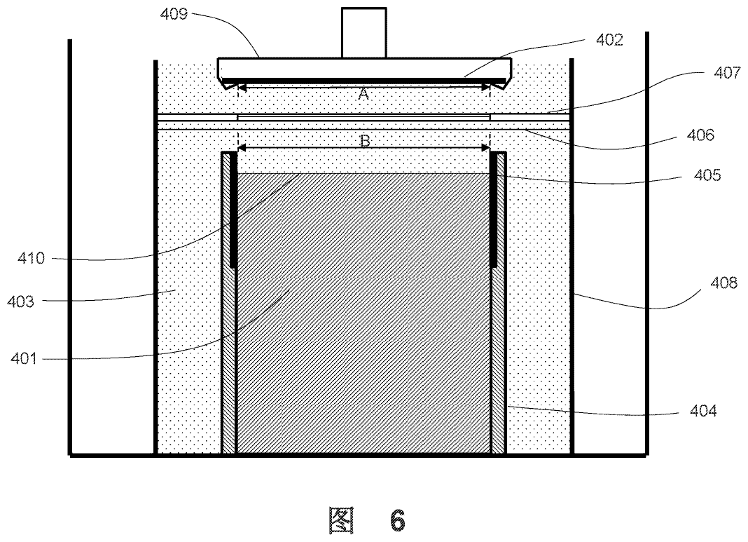

As shown in FIG. 6, during the electroplating process, the anode 401 is gradually consumed, and since the upper surface 410 of the anode 401 is consumed uniformly, the shape of the upper surface 410 always remains unchanged, and therefore the size of the cross-section of the electric field generated by the anode 401 remains unchanged.

In this embodiment, a ring of sealing member 405 is provided on the inner wall of the positioning cylinder 404, and the sealing member 405 comes in contact with at least the top of the side surface of the anode 401 in a sealing manner, so that the electroplating solution 403 does not leak to the side surface of the anode 401 and consume the side surface of the anode 401. Since the upper surface 410 of the anode 401 gradually decreases during the electroplating process, while usually a new anode is replaced before the anode 401 is entirely consumed, the sealing member 405 has at least a certain height in the vertical direction. This height can be a height that can ensure that the edge of the upper surface 410 of the anode 401 comes always in contact with the positioning cylinder 404 in a sealing manner.

A material of the positioning cylinder 404 can be metal, rigid insulating materials, etc., that does not participate in electrochemical reactions. The inner wall of the positioning cylinder 404 can be provided with a groove, and the sealing member 405 can be embedded in the groove.

### Embodiment 2

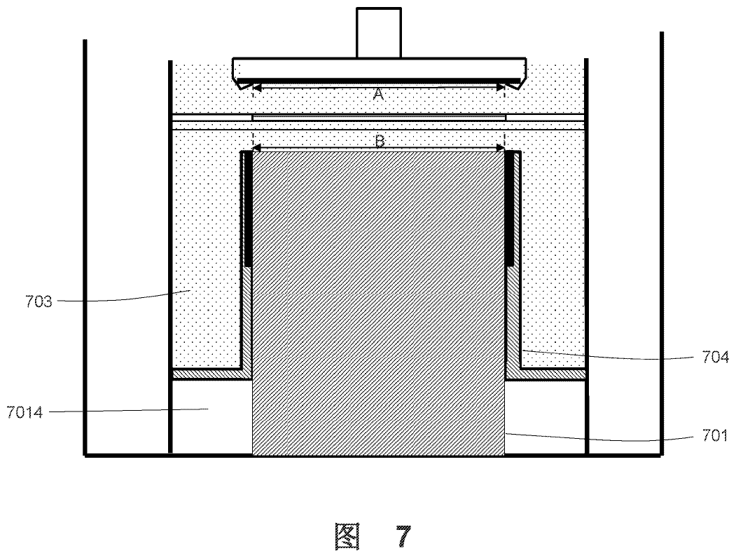

As shown in FIG. 7, this embodiment provides an electroplating device, and the structure of the electroplating device is essentially the same as the structure of the electroplating device in embodiment 1, the difference from embodiment 1 is that, in the electroplating device of this embodiment, the inner wall of the upper part of the positioning cylinder 704 comes in contact with the upper part of the anode 701 in a sealing manner, there is a space 7014 between the inner wall of the lower part of the positioning cylinder 704 and the lower part of the anode 701, and the electroplating solution 703 will not enter the space 7014, this space 7014 can be used to accommodate other components.

The remaining structures are the same as those in embodiment 1, and will not be repeated here.

### Embodiment 3

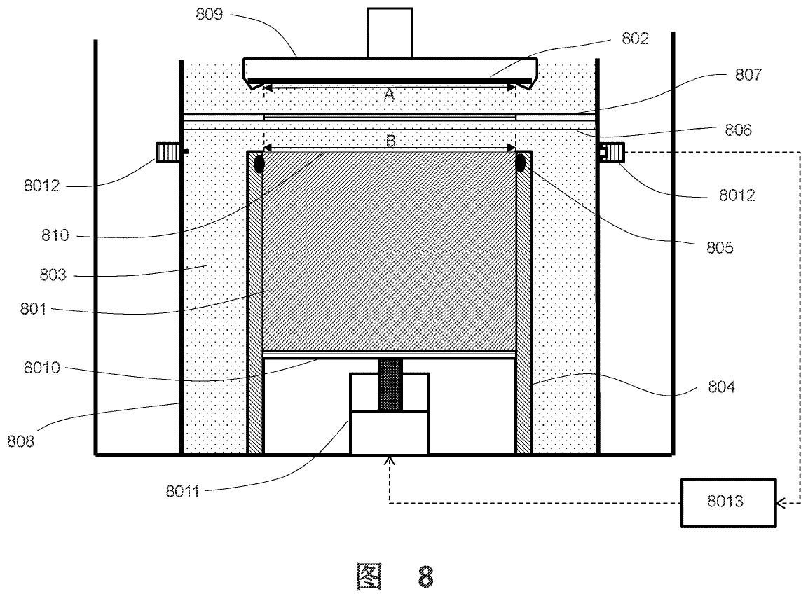

As shown in FIG. 8, this embodiment provides an electroplating device, comprising an anode 801, a positioning cylinder 804, an ion membrane 806, a diffusion plate 807, an electroplating tank 808, a clamp 809, an anode support plate 8010, a driving device 8011, a sensor 8012 and a controller 8013. The electroplating tank 808 is used to contain electroplating solution 803. The clamp 809 is used to hold a substrate 802. The anode 801 is located below the substrate 802, and an upper surface 810 of the anode 801 is parallel and opposite to the substrate 802. The ion membrane 806 is located above the anode 801, used to separate the anodic electroplating solution and cathode electroplating solution in the electroplating tank 808. The diffusion plate 807 is located between the ion membrane 806 and the substrate 802, and the diffusion plate 807 has a plurality of small holes for the electroplating solution 803 to pass through. The anode 801 is located inside the positioning cylinder 804. The top of the positioning cylinder 804 is open, and the bottom of the positioning cylinder 804 is connected to the inner wall of the electroplating tank 808. The shape of the inner wall of the positioning cylinder 804 matches the anode 801, with the center of the upper surface 810 of the anode 801 being aligned with the center of the substrate 802.

The inner wall of the positioning cylinder 804 is provided with an O-shaped sealing ring 805, the O-shaped sealing ring 805 comes in contact with the top of the side wall of the anode 801 in a sealing manner, such that in the surface region of the anode 801, only the upper surface 810 of the anode 801 is in contact with the electroplating solution 803, so the electric field generated by anode 801 is emitted entirely from the upper surface 810. The anode 801 may be cylindrical, and the size B of the upper surface 810 of the anode 801 is similar to the size A of the effective electroplating region of the substrate 802, so the size of the cross-section of the electric field generated by the anode 801 is the same (absolutely the same or approximately the same) as the size A of the effective electroplating region of the substrate 802, thus, the uniformity of the electric field distribution can be improved, so that the electric field intensity at each place of the effective electroplating region of the substrate 402 can be close to each other, thereby improving the uniformity of the electroplating height on the surface of the substrate 802.

Regarding the effective electroplating region of the substrate 802, this region refers to an region where metal is deposited. For example, when a circular substrate 802 with a diameter of 200 mm is held by the clamp 809, there is an annular region with a width of 1 mm on the edge of the substrate 802 that is wrapped by a lip seal of the clamp 809, this annular region will not be deposited with metal, so the diameter of the effective electroplating region of the substrate 802 is 198 mm.

The sensor 8012 is fixed to the outer wall of the electroplating tank 808, and the sensor 8012 detects whether the upper surface 810 of the anode 801 is located at a set height, so that the distance between the upper surface 810 of the anode 801 and the substrate 802 is maintained at a set value. Specifically, the sensor 8012 is flush with the upper surface 810 of the anode 801, and the upper surface 810 of the anode 801 is detected by the sensor 8012.

To prevent contamination or damage to the sensor 8012 from electroplating solution overflowing from the electroplating tank 808, a cover may be disposed over the sensor 8012.

The anode 801 consists of more than two small anodes assembled in a horizontal direction, and the bottom of the anode 801 is provided with an anode support plate 8010. The driving device 8011 is located below the anode support plate 8010, and the output shaft of the driving device 8011 is connected to the anode support plate 8010.

The controller 8013 is connected to the sensor 8012 and the driving device 8011 respectively.

During the electroplating process, the anode 801 is gradually consumed, and since the upper surface 810 of the anode 801 is consumed uniformly, the shape of the upper surface 810 always remains unchanged, and therefore the size of the cross-section of the electric field generated by the anode 801 remains unchanged. When the height of the upper surface 810 of the anode 801 is reduced, it cannot be detected by the sensor 8012, at this time, the sensor 8012 sends a first signal to the controller 8013, and after the controller 8013 receiving the first signal, the controller 8013 sends a command to the driving device 8011 to cause the output shaft of the driving device 8011 to move, raising the anode 801 up slowly until the sensor 8012 detects the upper surface 810 of the anode 801 again, at this time, the sensor 8012 sends a second signal to the controller 8013, and after the controller 8013 receiving the second signal, the controller 8013 sends a command to the driving device 8011, and the driving device 8011 stops moving. This allows the upper surface 810 of the anode 801 to always remain at the set height and the distance between the upper surface 810 of the anode 801 and the substrate 802 to be constant, making the process results more stable and not changing with the consumption of the anode.

It is also possible to infer the height change value of the upper surface 810 of the anode 801 based on the anode metal consumption calculated regularly by controller, so as to control the driving device 8011 to raise the upper surface 810 of the anode 801 up to the initial position. The anode metal consumption is related to factors such as electroplating current, power-on time, electroplating efficiency, etc., and the specific calculation method can be referred to the disclosed text of Japanese patent with Publication No. JP1983113399A. The amplitude of each action of the driving device 8011 should be as small as possible to prevent the upper surface 810 of the anode 801 from detaching from the O-shaped sealing ring 805, resulting in sealing failure.

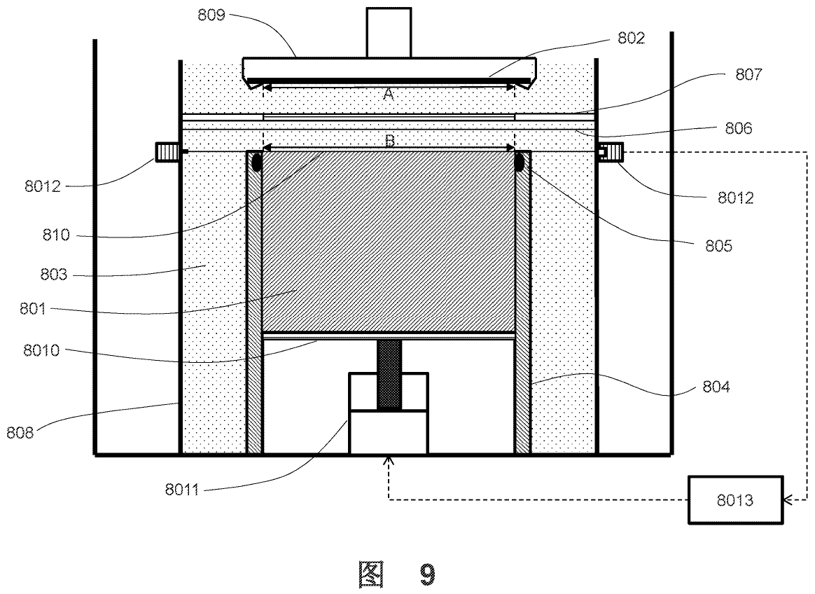

As shown in FIG. 9, after the electroplating process has been carried out for a period of time, the thickness of the anode 801 decreases, but the upper surface of the anode 801 remains at a constant height.

In this embodiment, the sensor 8012 is an infrared sensor, comprising a sending sensor and a receiving sensor. Both sides of the electroplating tank 808 are provided with view windows, if the infrared light emitted by the sending sensor passes through the view windows and is sensed by the receiving sensor on the other side, the upper surface 810 of the anode 801 is below the set height, at this time, the anode 801 needs to be raised to make the upper surface 810 of the anode 801 reach the set height.

In other embodiments, the sensor 8012 can also be a tactile sensor with an elastic contact, the contact of the sensor 8012 is installed on the top of the positioning cylinder 804. When the anode 801 is located below the set height, the contact is not in contact with the upper surface 8109 of the anode 801, at this time, the anode 801 needs to be raised to make the upper surface 8109 of the anode 801 contact with the contact.

The number of the O-shaped sealing ring 805 can be more than two.

### Embodiment 4

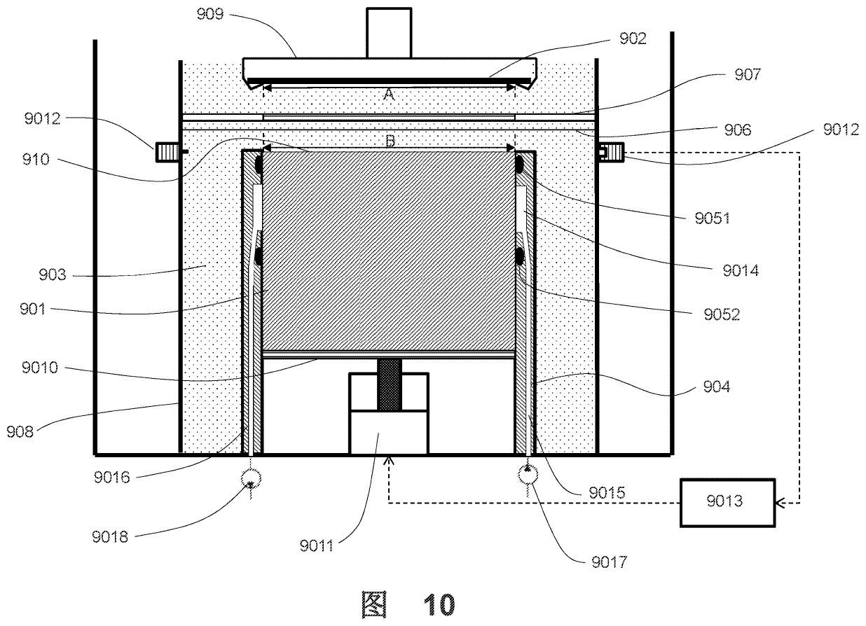

As shown in FIG. 10, this embodiment provides an electroplating device, comprising an anode 901, a positioning cylinder 904, an ion membrane 906, a diffusion plate 907, an electroplating tank 908, a clamp 909, an anode support plate 9010, a driving device 9011, a sensor 9012 and a controller 9013. The electroplating tank 908 is used to contain electroplating solution 903. The clamp 909 is used to hold a substrate 902. The anode 901 is located below the substrate 902, and an upper surface 910 of the anode 901 is parallel and opposite to the substrate 902. The ion membrane 906 is located above the anode 901, used to separate the anodic electroplating solution and cathode electroplating solution in the electroplating tank 908. The diffusion plate 907 is located between the ion membrane 906 and the substrate 902, and the diffusion plate 907 has a plurality of small holes for the electroplating solution 903 to pass through. The anode 901 is located in the positioning cylinder 904. The top of the positioning cylinder 904 is open, and the bottom of the positioning cylinder 904 is connected to the inner wall of the electroplating tank 908. The shape of the inner wall of the positioning cylinder 904 matches the anode 901, with the center of the upper surface 910 of the anode 901 being aligned with the center of the substrate 902.

The inner wall of the positioning cylinder 904 is provides with an upper sealing ring 9051, a lower sealing ring 9052, annular groove 9014, and a water inlet channel 9015 and a water outlet channel 9016 are provided in the positioning cylinder 904. The upper sealing ring 9051 comes in contact with the top of the side wall of the anode 901 in a sealing manner, so that in the surface region of the anode 901, only the upper surface 910 of the anode 901 is in contact with the electroplating solution 903, so the electric field generated by the anode 901 is emitted entirely from the upper surface 910. The anode 901 may be cylindrical, and the size B of the upper surface 910 of the anode 901 is similar to the size A of the effective electroplating region of the substrate 902, so the size of the cross-section of the electric field generated by the anode 901 is the same (absolutely the same or approximately the same) as the size A of the effective electroplating region of the substrate 902, thus, the uniformity of the electric field distribution can be improved, so that the electric field intensity at each place of the effective electroplating region of the substrate 902 can be made close to each other, thereby improving the uniformity of the electroplating height on the surface of the substrate 902.

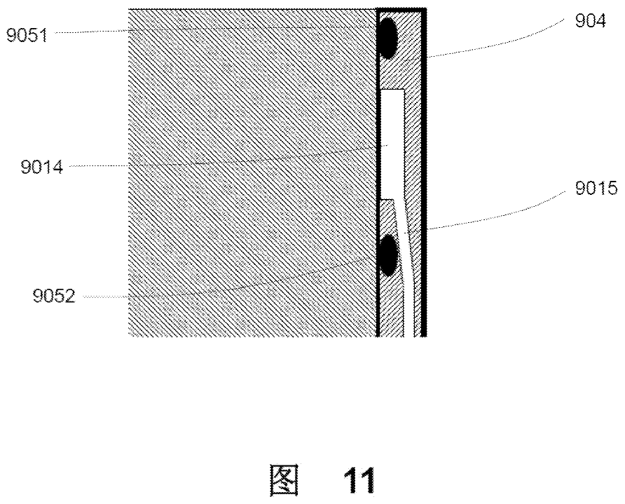

As shown in FIG. 11, the lower sealing ring 9052 is located below the upper sealing ring 9051, and the annular groove 9014 is located between the upper sealing ring 9051 and the lower sealing ring 9052. The top of the water inlet channel 9015 is connected to the annular groove 9014, and the bottom of the water inlet channel 9015 is connected to a water inlet pump 9017, the water inlet pump 9017 is used to transport liquid from the outside into the annular groove 9014. The top of the water outlet channel 9016 is connected to the annular groove 9014, and the bottom of the water outlet channel 9016 is connected to a water outlet pump 9018, the water outlet pump 9018 is used to discharge the liquid in the annular groove 9014 to the outside. The water inlet pump 9017 and the water outlet pump 9018 continue to operate to keep the liquid, such as water, in the annular groove 9014 in a flowing state, flesh liquid comes from the water inlet channel 9015 to the annular groove 9014, then flows out from water outlet channel 9016. When the upper sealing ring 9051 leaks, the electroplating solution 903 leaks downward and enters the annular groove 9014, and is then diluted by the liquid in the annular groove 9014, the diluted electroplating solution 903 flows out from the water outlet channel 9016 and will not accumulate in the annular groove 90014 and corrode the side wall of the anode 901. The lower sealing ring 9052 prevents the liquid from leaking downward and contaminating the driving device 9011. The water inlet channel 9015 and the water outlet channel 9016 are preferably provided at both radial ends of the annular groove 9014, so that the liquid in the annular groove 9014 can fully flow and the electroplating solution 903 can be fully diluted.

The sensor 9012 is fixed to the outer wall of the electroplating tank 908, and the sensor 8012 detects whether the upper surface 910 of the anode 901 is located at a set height, so that the distance between the upper surface 910 of the anode 901 and the substrate 902 is maintained at a set value. Specifically, the sensor 9012 is flush with the upper surface 910 of the anode 901, and the upper surface 910 of the anode 901 is detected by the sensor 9012.

To prevent contamination or damage to the sensor 9012 from electroplating solution overflowing from the electroplating tank 908, a cover may be provided over the sensor 9012.

The anode 901 consists of more than two small anodes assembled in a horizontal direction, and the bottom of the anode 901 is provided with the anode support plate 9010. The driving device 9011 is located below the anode support plate 9010, and the output shaft of the driving device 9011 is connected to the anode support plate 9010.

The controller 9013 is connected to the sensor 9012 and the driving device 9011 respectively.

During the electroplating process, the anode 901 is gradually consumed, and since the upper surface 910 of the anode 901 is consumed uniformly, the shape of the upper surface 910 always remains unchanged, and therefore the size of the cross-section of the electric field generated by the anode 901 remains unchanged. When the height of the upper surface 910 of the anode 901 is reduced, it cannot be detected by the sensor 9012, at this time, the sensor 9012 sends a first signal to the controller 9013, and after the controller 9013 receiving the first signal, the controller 9013 sends a command to the driving device 9011 to cause the output shaft of the driving device 9011 to move, raising the anode 901 up slowly until the sensor 9012 detects again the upper surface 910 of the anode 901, at this time, the sensor 9012 sends a second signal to the controller 9013, and after the controller 9013 receiving the second signal, the controller 9013 sends a command to the driving device 9011, and the driving device 9011 stops moving. This allows the upper surface 910 of the anode 901 to always remain at the set height and the distance between the upper surface 910 of the anode 901 and the substrate 902 to be constant, making the process results more stable and not changing with the consumption of the anode.

It is also possible to infer the height change value of the upper surface 910 of the anode 901 based on the anode metal consumption calculated regularly by controller, so as to control the driving device 9011 to raise the upper surface 910 of the anode 901 up to the initial position.

In this embodiment, the sensor 9012 is an infrared sensor, comprising a sending sensor and a receiving sensor. Both sides of the electroplating tank 908 are provided with view windows. If the infrared light emitted by the sending sensor passes through the view windows and is sensed by the receiving sensor on the other side, the upper surface 910 of the anode 901 is below the set height, at this time, the anode 901 needs to be raised to make the upper surface 910 of the anode 901 reach the set height.

### Embodiment 5

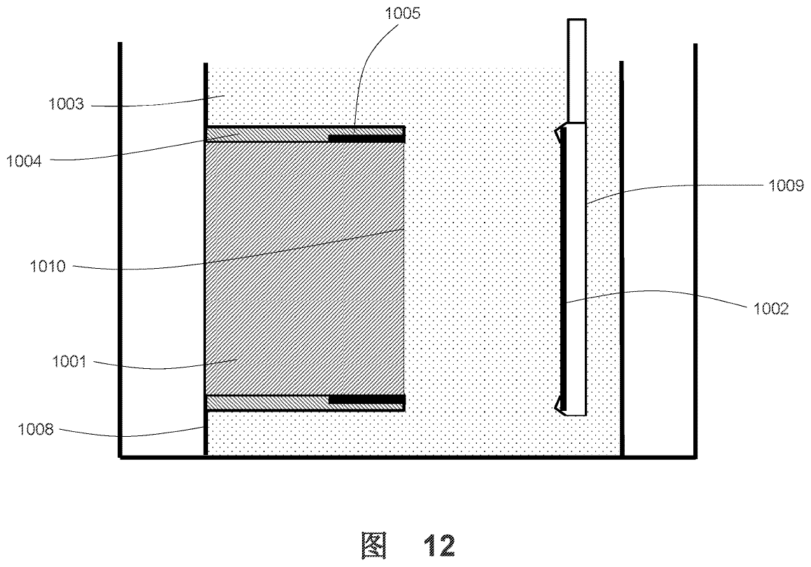

As shown in FIG. 12, this embodiment provides an electroplating device, comprising an anode 1001, a positioning cylinder 1004, an electroplating tank 1008 and a clamp 1009. The electroplating tank 1008 is used to contain the electroplating solution 1003. The clamp 1009 is used to hold the substrate 1002. The anode 1001 and the substrate 1002 are both vertically immersed in the electroplating solution 1003, and the right surface 1010 of the anode 1001 is parallel and opposite to the substrate 1002. The positioning cylinder 1004 is located in the electroplating tank 1008, and the bottom of the positioning cylinder 1004 is connected to the inner wall of the electroplating tank 1008. The anode 1001 is located inside the positioning cylinder 1004. The right end of the positioning cylinder 1004 is open. The shape of the inner wall of the positioning cylinder 1004 matches the anode 1001, with the center of the right surface 1010 of the anode 1001 being aligned with the center of the substrate 1002. A sealing member 1005 is provided at the contact part between the positioning cylinder 1004 and the anode 1001, such that in the surface region of the anode 1001, only the right surface 1010 of the anode 1001 is in contact with the electroplating solution 1003, so the electric field generated by anode 1001 is emitted entirely from the right surface 1010. The anode 1001 may be cylindrical, and the size of the right surface 1010 of the anode 1001 is similar to that of the effective electroplating region of the substrate 1002, so the size of the cross-section of the electric field generated by the anode 1001 is similar to that of the effective electroplating region of the substrate 1002, the uniformity of the electric field distribution can be improved, so that the electric field intensity at each place of the effective electroplating region of the substrate 1002 can be close to each other, thereby improving the uniformity of the electroplating height on the surface of the substrate 1002.

### Embodiment 6

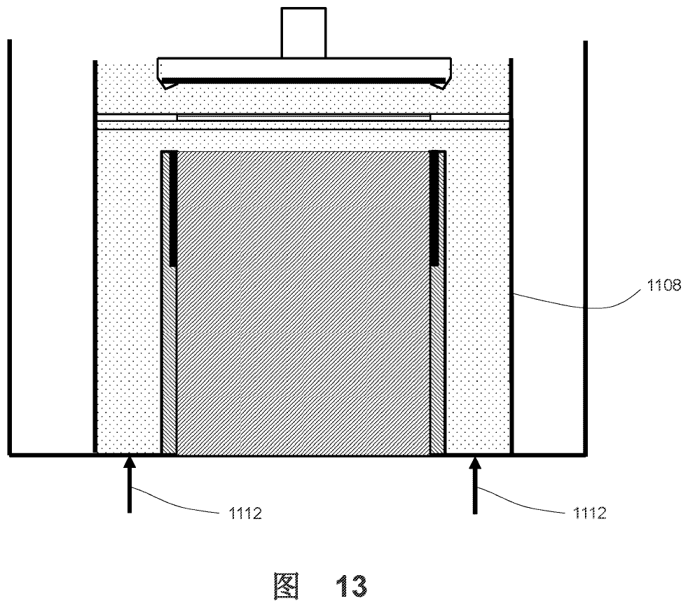

As shown in FIG. 13, this embodiment provides an electroplating device, this electroplating device comprises all the structures of the electroplating device described in embodiment 1, which will not be repeated here. In addition, a gas inlet 1112 is provided at the bottom of the electroplating tank 1108. The gas inlet 1112 is used to introduce air or oxygen into the electroplating solution so that the metal ions in the electroplating solution are fully oxidized and transformed into more stable metal ions under the action of oxygen.

### Embodiment 7

This embodiment provides an electroplating method, comprising:
set a positioning cylinder in an electroplating tank, place an anode inside the positioning cylinder, wherein the inner wall of the positioning cylinder comes in contact with the anode in a sealing manner, so that in the surface region of the anode, only a first surface of the anode is in contact with electroplating solution, the first surface of the anode is parallel and opposite to the substrate and the size of the first surface of the anode is similar to that of the effective electroplating region of the substrate, with the center of the first surface of the anode being aligned with to the center of the substrate;
set a distance between the first surface of the anode and the substrate;
calculate the change in distance between the first surface of the anode and the substrate, drive the anode to move toward the substrate until the distance between the first surface of the anode and the substrate reaches a set value.

### Embodiment 8

This embodiment provides an electroplating method, comprising:
set a positioning cylinder in an electroplating tank, place an anode inside the positioning cylinder, wherein the inner wall of the positioning cylinder comes in contact with the anode in a sealing manner, so that in the surface region of the anode, only a first surface of the anode is in contact with electroplating solution, the first surface of the anode is parallel and opposite to the substrate and the size of the first surface of the anode is similar to that of the effective electroplating region of the substrate, with the center of the first surface of the anode being aligned with to the center of the substrate;
set a distance between the first surface of the anode and the substrate;
detect the position of the first surface of the anode through a sensor and send signal to a controller;
when the distance between the first surface of the anode and the substrate exceeds the set value, the sensor sends a first signal to the controller, after the controller receiving the first signal, the controller sends a command to the driving device, and the driving device drives the anode to move toward the substrate until the distance between the first surface of the anode and the substrate is equal to the set value, at this time, the sensor sends a second signal to the controller, after the controller receiving the second signal, the controller sends a command to the driving device, and the driving device stops moving.

In order to make the metal ions in the electroplating solution more stable, a gas inlet is opened in the electroplating tank and air or oxygen is introduced into the electroplating solution, and the metal ions are fully oxidized and converted into more stable metal ions under the action of oxygen.

In summary, the present invention, by means of the above-described embodiments and related illustrations, has specifically and in detail disclosed the relevant technology, so that those skilled in the art can be implemented accordingly. The above-mentioned embodiments are only used to illustrate the present invention, and are not used to limit the present invention, the scope of rights of the present invention shall be defined by the Claims of the invention. Changes in the number of components or substitution of equivalent components as described herein shall still be within the scope of the present invention.

What is claimed is:

1. An electroplating device, comprising:
an electroplating tank, configured to contain an electroplating solution;
a clamp, configured to hold a substrate;
a positioning cylinder, located in the electroplating tank, one end of the positioning cylinder being open; and
an anode, located inside the positioning cylinder, wherein the positioning cylinder comes in contact with the anode in a sealing manner, and in the entire surface region of the anode, only a first surface comes in contact with the electroplating solution, the first surface being parallel and opposite to the substrate, with the center of the first surface being aligned with the center of the substrate, and the size of the first surface being similar to that of an effective electroplating region of the substrate.

2. The electroplating device according to claim 1, wherein the positioning cylinder comes in contact with a second surface of the anode in a sealing manner, the second surface is perpendicular to the first surface.

3. The electroplating device according to claim 1, wherein the positioning cylinder is arranged vertically, the inner wall of the positioning cylinder is provided with at least one ring of sealing member, the sealing member comes in contact with at least the edge of the first surface in a sealing manner, the sealing member has a certain height in the vertical direction.

4. The electroplating device according to claim 1, further comprising a driving device and a controller, the driving device being connected to the anode and the controller respectively, the controller regularly calculates the change in distance between the first surface of the anode and the substrate and controls the driving device, the driving device drives the anode to move toward the substrate to make the distance between the first surface of the anode and the substrate reach a set value.

5. The electroplating device according to claim 4, wherein the anode is arranged vertically, the anode consists of more than two small anodes assembled in horizontal direction, the bottom of the anode is provided with an anode support plate, the driving device is located below the anode support plate, the output shaft of the driving device is connected to the anode support plate.

6. The electroplating device according to claim 1, wherein the electroplating tank is provided with a gas inlet for introducing air or oxygen into the electroplating solution.

7. The electroplating device according to claim 1, further comprising a driving device, a sensor and a controller, the driving device being connected to the anode and the controller respectively, the sensor being connected to the controller, the sensor being arranged on the electroplating tank and configured to detect the position of the first surface of the anode, and sending a first signal or a second signal to the controller according to the detection result, the controller controlling the driving device according to the received first signal or second signal, the driving device driving the anode to move toward the substrate until the distance between the first surface of the anode and the substrate reaches a set value.

8. The electroplating device according to claim 7, wherein the sensor is an infrared sensor, comprising a sending sensor and a receiving sensor, the electroplating tank is provided with two view windows, the infrared light emitted by the sending sensor are received by the receiving sensor through the view windows.

9. The electroplating device according to claim 7, wherein the sensor is a tactile sensor with an elastic contact, the contact of the tactile sensor is installed on the positioning cylinder, when the distance between the first surface of the anode and the substrate is greater than the set value, the first surface of the anode does not contact the contact, at this time, the driving device drives the anode to move toward the substrate to make the first surface of the anode come into contact with the contact.

10. The electroplating device according to claim 7, wherein the inner wall of the positioning cylinder is provided with at least one O-shaped sealing ring, and the at least one O-shaped sealing ring comes in contact with the edge of the first surface in a sealing manner.

11. The electroplating device according to claim 7, wherein the positioning cylinder is arranged vertically, the inner wall of the positioning cylinder is provides with an upper sealing ring, a lower sealing ring and an annular groove, a water inlet channel and a water outlet channel are provided in the positioning cylinder, the upper sealing ring comes in contact with the edge of the first surface in a sealing manner, the lower sealing ring is located below the upper sealing ring, the annular groove is located between the upper sealing ring and the lower sealing ring, the top of the water inlet channel is connected to the annular groove, and the bottom of the water inlet channel is connected to a water inlet pump, the water inlet pump is used to transport liquid from the outside into the annular groove, the top of the water outlet channel is connected to the annular groove, the bottom of the water outlet channel is connected to a water outlet pump, the water outlet pump is used to discharge the liquid in the annular groove to the outside.

12. An electroplating method, comprising:
set a positioning cylinder in an electroplating tank, place an anode inside the positioning cylinder, wherein the inner wall of the positioning cylinder comes in contact with the anode in a sealing manner, so that in the surface region of the anode, only a first surface of the anode is in contact with electroplating solution, the first surface of the anode is parallel and opposite to the substrate, with the center of the first surface of the anode being aligned with to the center of the substrate;
set a driving device in the electroplating tank, wherein the driving device is contacted to the anode, calculate or detect the change in distance between the first surface of the anode and the substrate, and control the driving device moving to make the anode move toward the substrate until the distance between the first surface of the anode and the substrate reaches a set value.

13. The electroplating method according to claim 12, further comprising introducing air or oxygen into the electroplating solution.
